(19) United States
(12) Patent Application Publication
(10) Pub. No.: US 2008/0277941 A1
(43) Pub. Date: Nov. 13, 2008

(54) Generation of Electrical Power From Fluid Flows

(75) Inventors: Adrian Robert Bowles, Hampshire (GB); Stuart John Eaton, Hampshire (GB); Jonathan Geoffrey Gore, Hampshire (GB); Richard Carson McBride, Hampshire (GB); Ahmed Yehia Amin Rahman, Hampshire (GB)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: QINETIQ LIMITED, London (GB)

(21) Appl. No.: 12/097,131

(22) PCT Filed: Dec. 19, 2006
(86) PCT No.: PCT/GB06/04777

§ 371 Date: Jun. 12, 2008

(30) Foreign Application Priority Data
Dec. 21, 2005 (GB) 0525989.0

(51) Int. Cl. F03B 13/02; H01L 41/113

(52) U.S. Cl. 290/54; 310/339

(57) ABSTRACT

A device for the generation of electrical power from a fluid flow, and more particularly for harvesting power from flows downhole in oil or gas wells, comprises a cylinder or other blunt body (1) arranged crosswise to the flow and supported on the end of a sprung cantilever arm (3) held in a fixed mount, with freedom to oscillate in response to the shedding of a Karman vortex trail v from the′ body. The resultant motion of the body (1) and arm (3) is converted into electrical energy by piezoelectric material (5) which is attached to, and stressed by, flexure of the arm. Other arrangements of piezoelectric and inductive power generation from the oscillation of the device are described.

The present invention relates to the generation of electrical power from fluid flows.

The invention is particularly concerned with devices for use in generating power from fluids flowing downhole in oil and gas wells. Various kinds of equipment and instrumentation requiring electrical power are typically placed downhole in oil and gas wells, such as pumps, valves, actuators, flowmeters, strain gauges, temperature and pressure monitors, data loggers, telemetry transceivers and so on. Powering this equipment through conductors from the surface is difficult and expensive, in view of the very long lengths of cabling that may be required and the aggressive conditions which exist downhole, where breakage or damage to the conductors or their insulation at some point along their length is a serious risk. Storage batteries associated with the downhole equipment are, an alternative, but will be of limited life unless rechargeable and provided with a source of power for recharging. A need is therefore recognised for the provision of devices which can generate electrical power in situ downhole, and a readily-available energy source from which this power can be generated is the flow of the product or other fluids which passes through the well. Depending on the prevailing conditions and the type and location of the well, flows may be encountered comprising oil, gas, water, steam or mixtures of the same in multiple phases.

One aim of the present invention is therefore an electrical generating device or range of devices for harvesting power from downhole fluid flows of various kinds and which is capable of meeting the demands imposed by the downhole environment in terms of robustness, longevity, reliability, size and high temperature tolerance. In particular the adverse conditions experienced downhole generally make it unfeasible to employ conventional fluid-powered generation methods based on turbines or any other devices which depend on rotating or otherwise moving parts with mechanical bearings, linkages or other such interfaces.

Devices according to the invention are predicated upon the well-known fluid dynamic phenomenon of regular vortex shedding which is exhibited when a blunt object, such as a cylinder or the like, is placed crosswise to a fluid flow of appropriate Reynolds number. Flow past such bodies generally experiences boundary layer separation and the formation of a downstream turbulent wake containing distinct vortices which persist for some distance until they are damped out by the viscous action of the fluid. It is known that within a certain Reynolds number range a periodic flow pattern will develop with vortices formed at the points of separation being shed regularly in an alternating fashion from opposite sides of the body. The resultant regular vortex pattern is generally known as a Karman vortex trail or “street”, being so named because of Theodore von Karman's initial studies of the stability of these patterns. As the vortices are shed the corresponding uneven pressure distributions upon the opposite sides of the body generate an alternating dynamic loading on the body tending to cause physical oscillation of the same, and it is this effect which the present invention seeks to harness for conversion into electrical energy.

In one aspect the invention accordingly resides in a device for the generation of electrical power from a fluid flow comprising a blunt body arranged to be disposed, in use, generally crosswise to the flow and carried by support means with freedom to oscillate in response to the shedding of a Karman vortex trail by the interaction of the body and flow, and means for converting the consequent oscillatory motion of the body and/or support means into electrical energy.

Such a device can be structurally very simple, and in particular need not require any rotating parts or like mechanical interfaces, making it a suitable candidate for power generation downhole. However devices according to the invention are not restricted to such application and may be found more generally useful for power generation by interaction with a wide variety of fluids flowing e.g. in pipes or channels, or even free flows including the wind, tides and ocean currents.

In a preferred embodiment the blunt body is carried by a cantilever arm such that the body is permitted to oscillate by flexure of the arm.

The means for converting the oscillatory motion of the body and/or support means into electrical energy may be based on any suitable electrodynamic generation method, including magnetic induction or the application of electrostrictive, magnetostrictive or piezoelectric materials to the body/support system. A preferred method employs piezoelectric elements, which in the case of a cantilever arm support may be mounted on substantially all or selected parts of the arm or otherwise arranged so as to be stressed in response to its flexure.

It is particularly preferable if, in use of a device according to the invention, vortex shedding from the blunt body occurs at or sufficiently close to the natural frequency of the body/support system (or a harmonic thereof) so that resonance of the latter occurs. Under this condition, of course, its amplitude will be at a maximum and so the generation of electricity from the device can likewise be maximised. In the case of a cylindrical body it is known that the frequency of vortex shedding is directly proportional to the flow velocity and inversely proportional to the diameter of the body. Therefore in order for a device according to the invention to be excited in resonance over a useful range of different flow rates one measure which can be taken is to configure the body with a varying, e.g. stepped or tapering, diameter, so that for any given flow velocity the vortex trail can include a range of frequencies, related to the range of diameters presented to the flow. It follows that a frequency equivalent to the particular natural frequency of the respective body/support system can be included in the trails produced by the interaction of that body with a range of different flow velocities.

Other measures to ensure that resonance occurs within the device over a range of different flow rates could include a form of adaptive control of the natural frequency of the body/support system. For example in the case of a cantilever arm support its effective length and/or stiffness could be adjusted in response to sensed flow velocity.

In any event one simple way of maximising power generation from devices according to the invention is to provide an array of such devices in the same flow, with different members of the array configured to have different natural frequencies so that at least one member will be in resonance irrespective of the prevailing flow velocity, or fluid composition, within an anticipated range.

Features of the present invention will now be more particularly described, by way of example, with reference to the accompanying schematic drawings, in which:—

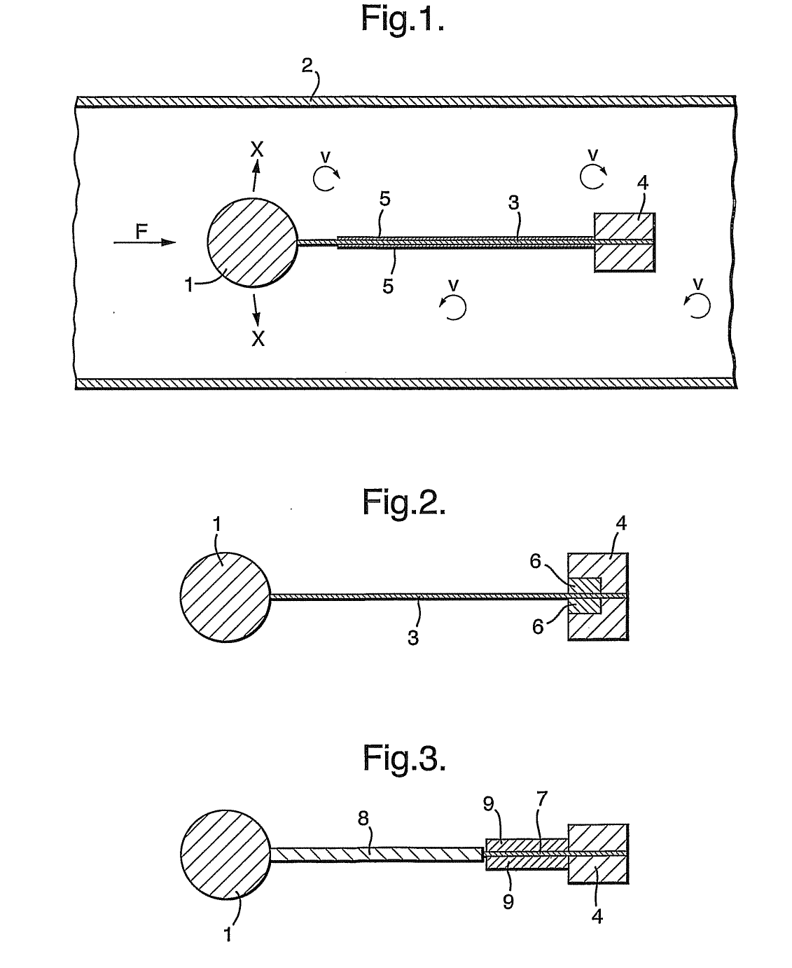

FIG. 1 is a longitudinal section through one embodiment of a power harvesting device according to the invention, installed in a pipe;

FIGS. 2 and 3 illustrate variants of the device of FIG. 1;

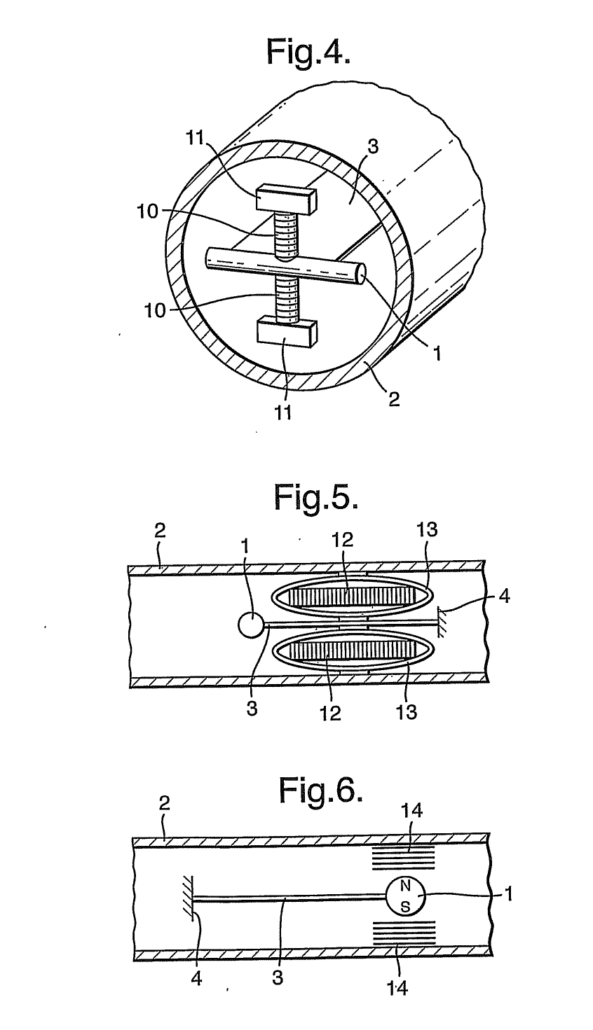

FIG. 4 is an end view of a further variant of the device of FIG. 1, installed in a pipe;

FIG. 5 is a side view of another embodiment of a power harvesting device according to the invention including a force-amplifying mechanism, installed in a pipe;

FIG. 6 is a side view of a further embodiment of a power harvesting device according to the invention, installed in a pipe;

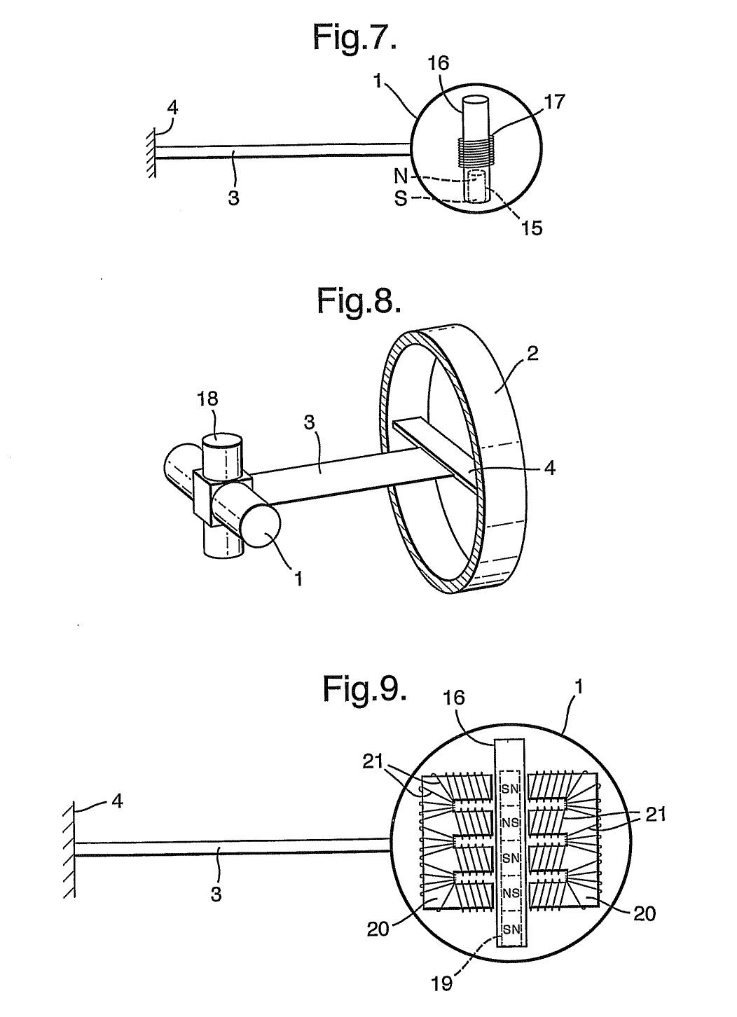

FIG. 7 is a side view Schematically illustrating the interior of a further embodiment of a power harvesting device according to the invention;

FIG. 8 is a pictorial view of a variant of the device of FIG. 7 installed in a pipe, with the pipe largely broken away;

FIG. 9 is a side view schematically illustrating the interior of another variant of the device of FIG. 7;

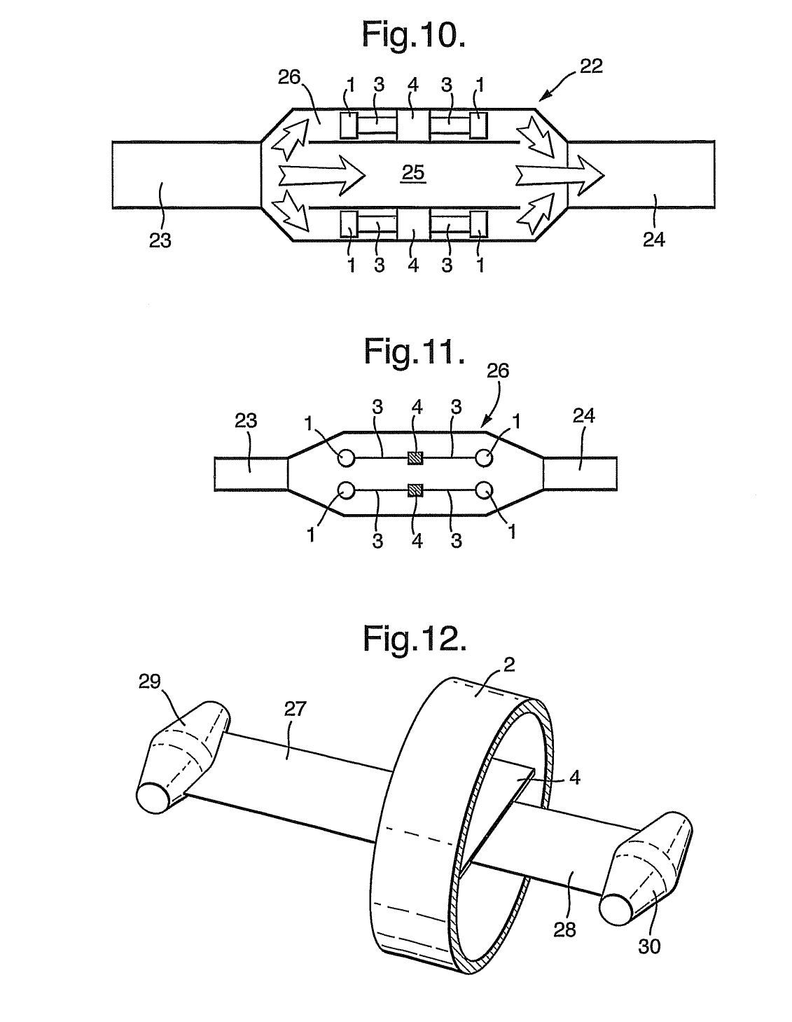

FIGS. 10 and 11 are schematic sections through fittings comprising several devices according to the invention; and

FIG. 12 is a pictorial view of a pair of devices according to a further embodiment of the invention installed in a pipe, with the pipe largely broken away.

With reference to FIG. 1, the illustrated embodiment of the invention comprises a cylindrical body 1 supported to lie within the central region of the interior of a pipe 2 located in a downhole region of an oil or gas well, and with the axis of the cylinder 1 substantially perpendicular to the axis of the pipe. In this respect the body 1 is carried at the end of a blade 3 of e.g. spring steel which is held at its opposite end in a fixed mount 4 extending across and rigidly attached to the inside of the pipe 2. Both the upper and lower (as viewed) surfaces of the blade 3 are covered along most of its length with patches of piezoelectric material 5. In principle any suitable form of piezoelectric ceramic or polymer material may be employed, although one which has been found to perform well in tests of a device of this kind is a piezoelectric macro fibre composite (MFC) patch comprising many individual ceramic fibres bonded between thin polyimide sheets.

In accordance with known fluid dynamic principles, when the body 1 is subjected to a flow of fluid through the pipe 2 within a certain Reynolds number range, notionally indicated by the arrow F in FIG. 1, vortices will tend to be shed regularly in an alternating fashion from the upper and lower (as viewed) sides of the body, establishing a so-called Karman vortex trail as notionally indicated at v in FIG. 1. The corresponding alternating dynamic loading on the body 1 will tend to cause the latter to oscillate in the vertical (as viewed) plane as notionally indicated by the arrows X, with consequent flexure of the cantilever arm support constituted by blade 3. Flexure of the blade 3 will stress each piezoelectric patch 5 alternately in compression and tension, in opposite phase to each other, thereby generating electric charges from the patches in pulses corresponding to the oscillation of the body 1/blade 3 system. Electrical leads (not shown) connect each patch 5 to an external circuit from which an associated battery or capacitor can be charged for powering downhole instrumentation or other electrical equipment.

Devices of the kind illustrated in FIG. 1 have been tested over a range of flowrates and using a range of fluids, namely (i) single phase water, (ii) single phase oil, (iii) two-phase oil and water, and (iv) multiphase gas, oil and water, with Reynolds numbers ranging from 4,500 to 312,000. Over a useful range of flowrates in all three of the liquid phase examples, the observed behaviour of the devices was to oscillate in the flow at the respective natural frequency of the body/blade system, the amplitude of the oscillation increasing up to a maximum where the vortex shedding frequency associated with the flow velocity matched the natural frequency of the device (i.e. resonance occurred). Subsequent increase in the flow velocity led to a decrease in amplitude from the resonant condition but in some cases still higher flow rates excited harmonic frequencies of the device leading to a secondary increase in amplitude. The behaviour in multiphase gas, oil and water was more intermittent and transient but most of the dynamic behaviour of the devices still occurred at the respective natural frequency. Flows of this kind can be highly turbulent and impose large impulse forces on the devices, but this can actually enhance the electrical power output by increasing the stress on the piezoelectric patches. If necessary to prevent the piezoelectric material becoming overstrained and risking fracture, stops may be incorporated in the design to limit the displacement of the body 1 and consequent flexure of the blade 3.

FIGS. 2 and 3 illustrate variants of the structure of the device shown in FIG. 1.

In FIG. 2, instead of the thin piezoelectric patches 5 along the length of the blade 3, relatively high volume piezoelectric elements 6 are located between the fixed mount 4 and the blade 3 at its root, which is the most highly stressed region of the device when the body 1 oscillates.

In FIG. 3, a two-piece cantilever arm is provided in place of the blade 3, comprising a relatively short length of spring steel 7 at the root followed by a length of stiffer stainless steel 8. In this example the flexure of the arm is concentrated at the root where the spring steel 7 can be covered with thicker piezoelectric elements 9 than the patches 5.

Although the devices of FIGS. 1 to 3 are shown with the axes of both the pipe 2 and body 1 extending horizontally these devices can in principle be used in any other angular or rotational orientation, so long as the body 1 is generally crosswise to, and its cantilever arm is generally parallel to, the incident fluid flow. Similarly although they are shown with an incident flow from the left of the body 1 as viewed (i.e. on the face of the body remote from its connection to the cantilever arm) the behaviour of the device will be generally the same if the flow direction is reversed, with a Karman vortex trail then being established on the downstream side of the body 1 to the left as viewed in these Figures.

FIG. 4 illustrates a further variant of the devices described above where, as an alternative or in addition to the piezoelectric material 5, 6 or 9, stacks of piezoelectric discs 10 are mounted on the body 1 crosswise to its own axis (above and below the body in the orientation shown in the Figure), with masses 11 fixed to the free end of each stack. As the body 1 oscillates in use of this device, the inertial effect of each mass 11 is to stress the respective piezoelectric stack 10 between itself and the body alternately in compression and tension, the two stacks being stressed in opposite phase to each other, thereby generating electric charges from the stack in pulses corresponding to the oscillation of the body 1. The effect may be enhanced if a small spring (not shown) is placed between each piezoelectric stack 10 and the body 1, the compression and extension of which, during opposite strokes of the body's oscillation, can concentrate the inertial effects over a shorter period and result in higher compressive and tensile stresses being generated in the piezoelectric material with consequent increase in the charge generated.

It is observed that in use of the embodiment of FIG. 4 the cylindrical piezoelectric stacks 10 will also tend to shed a Karman vortex trail within the flow of fluid passing through pipe 2, and at right angles to the trail shed from the body 1. Since the blade 3 is stiff in the direction of the dynamic loading induced by the vortices from the stacks 10, however, this phenomenon should not interfere with the essentially uniplanar oscillation of the body 1 and blade 3.

Since the electrical output of a piezoelectric material is generally proportional to the level of induced stress but such materials exhibit relatively small strain rates even under high forces, it may be advantageous in a device according to the invention, which utilises piezoelectric energy conversion, to employ some form of mechanical linkage between the oscillating body/support system and the piezoelectric material which converts the relatively high displacement/low force motion of the former to a relatively low displacement/high force action applied to the latter. FIG. 5 depicts one such configuration. This again shows a device comprising the body 1, blade 3 and fixed mount 4 installed in a pipe 2. In this case, however, there are stacks of piezoelectric discs 12 disposed on opposite sides of the blade 3 in parallel to the pipe 2. An elliptical spring metal ring 13 surrounds each piezoelectric stack 12 with the respective stack extending along the longer axis of the respective ellipse and firmly attached thereto at its opposite ends. In the direction of their shorter axes the elliptical springs 13 are each attached between the blade 3 and the adjacent wall of the pipe 2.

In use of the device of FIG. 5, oscillation of the body 1 and consequent flexure of the blade 3 (upwards and downwards from the illustrated central position in the orientation of the pipe viewed in the Figure) causes each elliptical spring 13 to be alternately squeezed and expanded by the blade, (in opposite phase to each other), along the shorter axis of the respective ellipse. Due to the shape of the springs 13 this in turn causes each one to alternately expand and contract along its longer axis, but through a smaller dimension than the orthogonal contraction and expansion, and consequently apply alternately tensile and compressive stresses to the piezoelectric stacks 12 which generate electric charges accordingly. The force which can be applied to the stacks 12 by this action is amplified in comparison with the force applied by the blade 3 to the springs 13 in inverse proportion to the reduction in displacement of the springs along their longer axes in comparison to the displacement along their shorter axes caused by the blade 3.

FIG. 6 illustrates another embodiment of a power harvesting device according to the invention, where in this case electrical energy is generated by electromagnetic induction. As before, a cylindrical body 1 is carried at the end of a sprung cantilever arm 3 from a fixed mount 4 in the pipe 2 so as to oscillate in response to the shedding of a Karman vortex trail when exposed to fluid flow. In this case, however, the body 1 is permanently magnetised with poles along its upper and lower faces (in the orientation of the pipe 2 shown in the Figure), and rectangularly-wound coils 14 attached to the walls of the pipe 2 are juxtaposed to these faces so that as the body oscillates and partially penetrates into and out of each coil pulses of electricity will be alternately induced. Electrical leads (not shown) extend from the coils 14 to an external circuit from which an associated battery or capacitor can be charged for powering downhole instrumentation or other electrical equipment.

If the fluid within which the device of FIG. 6 operates has a ferrous content then there can be a build up of debris on the magnetised body 1, adversely affecting the performance of the device. An alternative configuration utilising magnetic induction for power conversion, and which addresses this problem by shielding the magnetic element from the flow, is shown in FIG. 7. Within the body 1 in this case a bar-like permanent magnet 15 is trapped in a chamber 16 extending crosswise to the axis of the body but with freedom to slide therein so that as the body oscillates in use of the device, (up and down in the orientation shown in the Figure), the magnet is impelled to repeatedly shuttle from one end of the chamber to the other, by virtue its own inertia. A coil 17 is wound around the central region of the chamber 16 and each time that the magnet 15 passes through the coil, in the course of its excursions within the chamber, pulses of electricity will be induced in the coil. Electrical leads (not shown) extend out of the device from the coil 17 to a circuit from which an associated battery or capacitor can be charged for powering downhole instrumentation or other electrical equipment.

Improved performance may be derived from the device of FIG. 7 if the magnet 15 is suspended within the chamber between a pair of springs (not shown) and the magnet/spring system is tuned so as to resonate within the chamber at the same frequency as but in opposite phase to the resonance of the body 1/arm 3 system. Operating in this mode will maximise the relative speed of traverse of the magnet 15 through the coil 17 and consequently maximise the rate of change of flux and correspondingly induced voltage in the coil.

FIG. 8 illustrates a variant of the device of FIG. 7 employing a larger assembly of magnet, coil and chamber where in this case the chamber housing the magnet is in the form of a cylinder 18 which is of similar dimensions to the body 1 and forms therewith a cruciform assembly at the end of the blade 3. As in the case of the device of FIG. 4, however, this should not interfere with the essentially uniplanar oscillation of the body 1 and blade 3.

FIG. 9 illustrates a further variant of the device of FIG. 7 where in this case the magnet 15 is replaced by a stack of magnets 19 (or a single multipole magnet) presenting an alternating series of poles along opposite sides of the stack. Facing each side of this magnetic stack are multi-limbed magnetically-permeable cores 20 wound with coils 21. In use of this device, as the body 1 oscillates the magnetic stack 19 is impelled to repeatedly shuttle from one end of the chamber 16 to the other, with the consequence that with each excursion of the stack the polarity of the portion of it which faces each limb of a core 20 reverses. Electrical pulses are therefore induced in the coils 21 corresponding to the oscillation of the body 1, and since in this embodiment the cores 20 provide a return path for the magnetic flux, and the multiple poles will result in a larger rate of change of magnetic flux in the cores, it will be a more efficient generator of power than the embodiment of FIG. 7, albeit involving greater mass.

In either of the embodiments of FIGS. 7 and 9 a plurality of chambers 16 together with magnets, coils and (where applicable) cores could be provided, spaced across the width of the body 1.

In practice it is likely that a multiplicity of devices according to the invention will be installed to collectively meet the power demands of downhole equipment. It is also desirable in some circumstances that the bore of downhole pipes is left unobstructed to permit the passage of tools or instrumentation through the system. For this reason fittings such as illustrated in FIG. 10 may be provided. In this example a fitting 22 is installed between two pipe lengths 23 and 24. The fitting 22 has a central passage 25 of similar bore to the pipes 23/24, surrounded by an annular passage 26 through which a proportion of the flow passing into the fitting is diverted as indicated by the arrows in the Figure. Within the passage 26 there are seen several devices of any suitable kind previously described, comprising respective bodies 1 held on cantilever arms 3 from fixed mounts 4. Further arrays of such devices may be provided at circumferentially spaced intervals around the interior of the annular passage 26.

FIG. 11 illustrates a divergent-convergent fitting 26 similar to the fitting 22 with a central section of increased diameter as compared to the pipe lengths 23 and 24 to which it is fitted and in which four power harvesting devices comprising bodies 1 and cantilever arms 3 are supported from two fixed mounts 4 extending chordwise of the fitting. This variant avoids the separate annular passage 26 which might present a risk of clogging in particularly contaminated flows.

As previously indicated, for maximum power generation from devices according to the invention it is desirable that they operate in a resonant condition. In order to increase the range of flowrates at which resonance will occur, therefore, in any of the above-described embodiments the respective cylindrical body 1 may be replaced by a body of stepped or tapering diameter so that the vortex trails from such bodies will tend to include a range of different frequencies. In addition, arrays of such devices can be used where the individual devices have different natural frequencies, for example by using components of different geometry, mass or stiffness.

An example of both of these measures is shown in FIG. 12. In this example there is a pipe 2 with a fixed mount 4 from which two cantilever arms 27 and 28 extend in opposite directions and carry respective bodies 29 and 30. Each body 29,30 is of tapered diameter and effectively comprises two frustoconical surfaces extending to either side of a central maximum-diameter portion. Each cantilever arm 27,28 is of the same spring steel material but they are of different lengths to give the respective body/arm systems 29/27 and 30/28 different natural frequencies.

1. A device for the generation of electrical power from a fluid flow comprising a blunt body arranged to be disposed, in use, generally crosswise to the flow and carried by a support with freedom to oscillate in response to the shedding of a Karman vortex trail by the interaction of the body and flow, and an energy converter for converting the consequent oscillatory motion of the body and/or support into electrical energy.

2. (canceled)

3. A device according to claim 1 wherein said body is carried by a cantilever arm such that the body is permitted to oscillate by flexure of the arm and said energy converter comprises piezoelectric material arranged to be stressed by flexure of said arm.

4. A device according to claim 3 wherein said piezoelectric material is attached to said arm along substantially all or part of its length.

5. A device according to claim 3 wherein said piezoelectric material is located between said arm and a fixed support for said arm.

6. A device according to claim 3 wherein said arm has a flexible root portion and a stiffer portion between said root portion and said body, and said piezoelectric material is attached to said root portion.

7. A device according to claim 3 comprising a force-amplifying mechanism between said arm and said piezoelectric material.

8. A device according to claim 7 wherein said force-amplifying mechanism comprises an elliptical spring arranged to be compressed and expanded along its shorter axis by flexure of said arm and said piezoelectric material is arranged to be stressed by consequent expansion and compression of said spring along its longer axis.

9. (canceled)

10. A device according to claim 1 wherein piezoelectric material is connected between said body and a mass which is caused to oscillate when said body oscillates by virtue of its connection through said piezoelectric material to said body and the inertia of which consequently stresses said piezoelectric material.

11. A device according to claim 10 further comprising a spring between said body and said piezoelectric material.

12. (canceled)

13. A device according to claim 1 wherein said body is magnetised and said energy converter comprises at least one coil juxtaposed to said body within which electricity is induced in response to oscillation of said body.

14. A device according to claim 1 wherein said energy converter comprises a magnet located with freedom to oscillate relative to said body by virtue of its own inertia when said body oscillates, and at least one coil within which electricity is induced in response to such oscillation of the magnet.

15. A device according to claim 14 wherein a said coil surrounds a region through which said magnet is arranged to oscillate.

16. A device according to claim 14 wherein said magnet is a multi-pole magnetic structure and said coil or coils surround a magnetically-permeable multi-limbed core which is juxtaposed to a region within which said magnet is arranged to oscillate.

17. A device according to claim 14 wherein said magnet is suspended by one or more springs relative to said body.

18. A device according to claim 17 wherein the system comprising said magnet and spring(s) is arranged to resonate in opposite phase to the resonance of said body.

19. A device according to claim 14 wherein said magnet and coil(s) are enclosed within said body.

20-21. (canceled)

22. A device according to claim 1 wherein said body is substantially in the form of one or more bodies of rotation and has a stepped or tapering diameter.

23. A device comprising a pair of devices according to claim 1 comprising a pair of cantilever arms extending in opposite directions from a fixed support and carrying respective said bodies such that said bodies are permitted to oscillate by flexure of respective said arms.

24. A device according to claim 23 wherein the natural frequencies of the two arm and body systems differ.

25. A device according to claim 24 wherein the lengths of said cantilever arms differ.

26. A fitting comprising a central passage for fluid flow surrounded by an annular passage through which a portion of the flow through the fitting can pass, and one or more devices according to claim 1 within said annular passage.

27. A fitting comprising a divergent-convergent section for fluid flow and a plurality of devices according to claim 1 within said section.

28. An installation comprising a plurality of devices according to claim 1 wherein different said devices within the installation have body and support means systems of different natural frequencies.

29. An oil or gas well having one or more devices or fittings according to claim 1 installed downhole.

30. A method of generating electrical power from a fluid flow which comprises exposing one or more devices according to claim 1 to such flow so that the body of any such device is caused to oscillate in response to the shedding of a Karman vortex trail by the interaction of the body and flow.

31. A method according to claim 30 wherein the frequency of said vortex shedding substantially corresponds to the natural frequency of the body and support system of the respective device.
